(19) United States
(12) Patent Application Publication
(10) Pub. No.: US 2013/0334639 A1
(43) Pub. Date: Dec. 19, 2013

(54) PHOTODIODE WITH REDUCED DEAD-LAYER REGION

(71) Applicant: David Kerwin, Colorado Springs, CO (US)

(72) Inventor: David Kerwin, Colorado Springs, CO (US)

(73) Assignee: Aeroflex Colorado Springs Inc., Colorado Springs, CO (US)

(21) Appl. No.: 13/526,129

(22) Filed: Jun. 18, 2012

(51) Int. Cl. H01L 31/0232; H01L 31/02; H01L 31/0224

(52) U.S. Cl. 257/432; 257/431; 257/443; 438/57; 257/E31.124; 257/E31.11; 257/E31.127

(57) ABSTRACT

A photodiode structure having an illuminated front-side surface and a back-side surface includes a front-side doped layer having a first conductivity type, a back-side doped layer having the first conductivity type, a front-side active cell region made sensitive to light by the action of at least one plug region formed in the front-side doped layer having a second conductivity type, and a front-side inactive cell region substantially insensitive to light, wherein the first and second conductivity types are opposite conductivity types.

### RELATED CASE INFORMATION

This application is related to application Ser. No. 13/218,308, entitled “Wafer Structure for Electronic Integrated Circuit Manufacturing,” filed Aug. 25, 2011, and application Ser. No. 13/218,273, entitled “Wafer Structure for Electronic Integrated Circuit Manufacturing,” filed Aug. 25, 2011, and application ser. No. 13/218,335, entitled “Wafer Structure for Electronic Integrated Circuit Manufacturing,” filed Aug. 25, 2011, and application Ser. No. 13/218,345, entitled “Wafer Structure for Electronic Integrated Circuit Manufacturing,” filed Aug. 25, 2011, and application Ser. No. 13/218,352, entitled “Wafer Structure for Electronic Integrated Circuit Manufacturing” filed Aug. 25, 2011, and application Ser. No. 13/218,292, entitled “Wafer Structure for Electronic Integrated Circuit Manufacturing,” filed Aug. 25, 2011, all of which are herein incorporated by reference as if set forth in their entireties.

### FIELD OF THE INVENTION

The present invention relates to photodiodes and, more particularly, to a structure and method to improve the photodiode response in front-illuminated, back-side contacted, bonded-wafer, Through Silicon Via (TSV) photodiodes.

### BACKGROUND OF THE INVENTION

An example of the current state-of-the-art in front-illuminated, back-side contacted, TSV photodiodes is illustrated in U.S. Pat. No. 7,741,141. In this and other patents referenced therein, a photodiode structure is formed consisting of a first doping concentration proximate to a front-side surface, and a second doping concentration proximate to a back-side surface, the front-side doping type being opposite to the backside doping type, with an insulating (intrinsic) region separating the front-surface doping region from the back-surface doping region. The structure formed is either a p-i-n (p-type or anode, insulating, n-type or cathode) or n-i-p (n-type or cathode, insulating, p-type or anode) diode structure. This photodiode structure is often used as part of an X-ray detector comprised of a scintillation material (such as Cadmium Tungstate or Cesium Iodide) attached to the photodiode such that visible light generated in the scintillation crystal by X-rays absorbed therein is subsequently absorbed in the photodiode, generating an electrical current which may be detected and quantized by various electronic means. However, an optical draw-back of this type of structure is the fact that any light absorbed in the non-depleted portion of the front-side doping region (whether anode or cathode) cannot contribute to the desired photo-current, since the electron-hole pairs generated recombine quickly before reaching the depleted region of the photodiode. Such a non-depleted region is called the dead-layer.

A typical prior photodiode structure 10 is shown in cross section in FIG. 1. As previously described an n⁺⁺ type cathode layer 18 is shown, as well as an n⁻ i-layer (collection layer) 16, and a patterned p⁺ type anode (dead layer) 14, separated by patterned isolation layers 12. FIG. 1 depicts the anode 14 being struck by photons 19. A plan view of the photodiode 20 is shown in FIG. 2. The plan view simply shows four p⁺ anodes 24 separated by an isolation region 22.

FIG. 3 is a graph 30 that illustrates the percentage 32 of the incident light signal lost as a function of the depth of the front-side dead-layer region, using the absorption coefficient of silicon at 490 nm wavelength, a wavelength approximately near the peak emission of Cadmium Tungstate. As can be seen from FIG. 3, a dead layer of only 0.2 microns depth can cause a loss of signal of up to 20% at 490 nm. While the loss due to the dead layer decreases for longer wavelengths, it can still be significant (>10%).

Thus, what is desired is an alternative photodiode structure that minimizes the dead layer so that the photodiode response can be maximized.

### BRIEF SUMMARY OF THE INVENTION

A photodiode structure having an illuminated front-side surface and a back-side surface comprise a front-side doped layer having a first conductivity type; a back-side doped layer having the first conductivity type; a front-side active cell region made sensitive to light by the action of at least one plug region formed in the front-side doped layer having a second conductivity type; and a front-side inactive cell region substantially insensitive to light, wherein the first and second conductivity types are opposite conductivity types. The photodiode includes a through-via traversing the at least one plug region or the inactive cell region. In an embodiment of the invention, the first conductivity comprises an n-type conductivity, and the second conductivity comprises a p-type conductivity. The inactive cell region comprises a pixel isolation region that can be formed using a silicon trench, a heavily doped region of the first conductivity type, or other deep trenches filled with non-conductive materials including oxide or a combination of oxide and intrinsic, polycrystalline semiconductor. In an embodiment of the invention, the back-side doped layer comprises a cathode layer. The photodiode structure of the present invention can be fabricated in silicon, GaAs, or other semiconductor materials.

### BRIEF DESCRIPTION OF THE DRAWINGS

The following detailed description of the preferred embodiments of the present invention will be better understood when read in conjunction with the following drawings. The embodiments shown in the drawings illustrate the preferred embodiments of the present invention; however, the invention is not limited to the precise arrangements and instrumentalities shown. Drawings are not to scale.

In the drawings:

FIG. 1 is a cross-sectional view of a photodiode according to the prior art including a dead layer;

FIG. 2 is a plan view of the prior art photodiode shown in FIG. 1;

FIG. 3 is a graph of the lost signal as a function of dead layer depth in microns associated with the photodiode of FIG. 1;

FIG. 4 is a cross-sectional view of a photodiode according to the present invention;

FIG. 5 is a detailed cross-sectional view of the photodiode according to the present invention;

FIG. 6 is a front-side plan view of the photodiode with the front-side dielectric and metal interconnection layers omitted;

FIGS. 7 through 9 are detailed front-side plan views of alternative embodiments of the photodiode of the present invention;

FIG. 10 is a detailed front-side plan view of an embodiment of the photodiode of the present invention showing the front-side metal interconnections;

FIG. 11 is a process flow diagram showing cross-sectional view of the photodiode of the present invention at various points during the fabrication process;

FIG. 12 is a back-side plan view of the photodiode showing the back-side metal interconnections; and

FIG. 13 is a diagram of an X-ray imaging system incorporating the photodiode of the present invention.

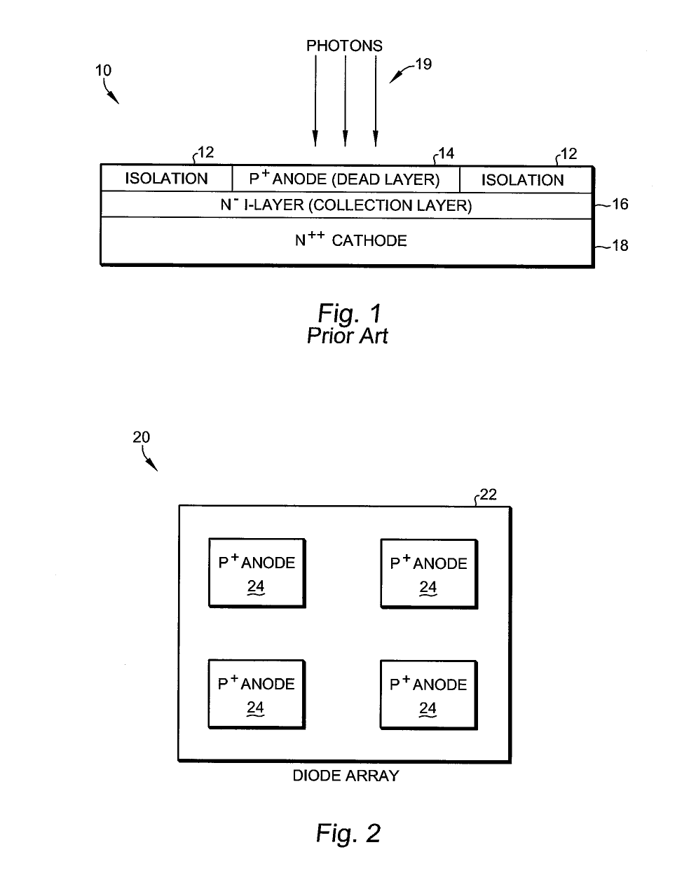

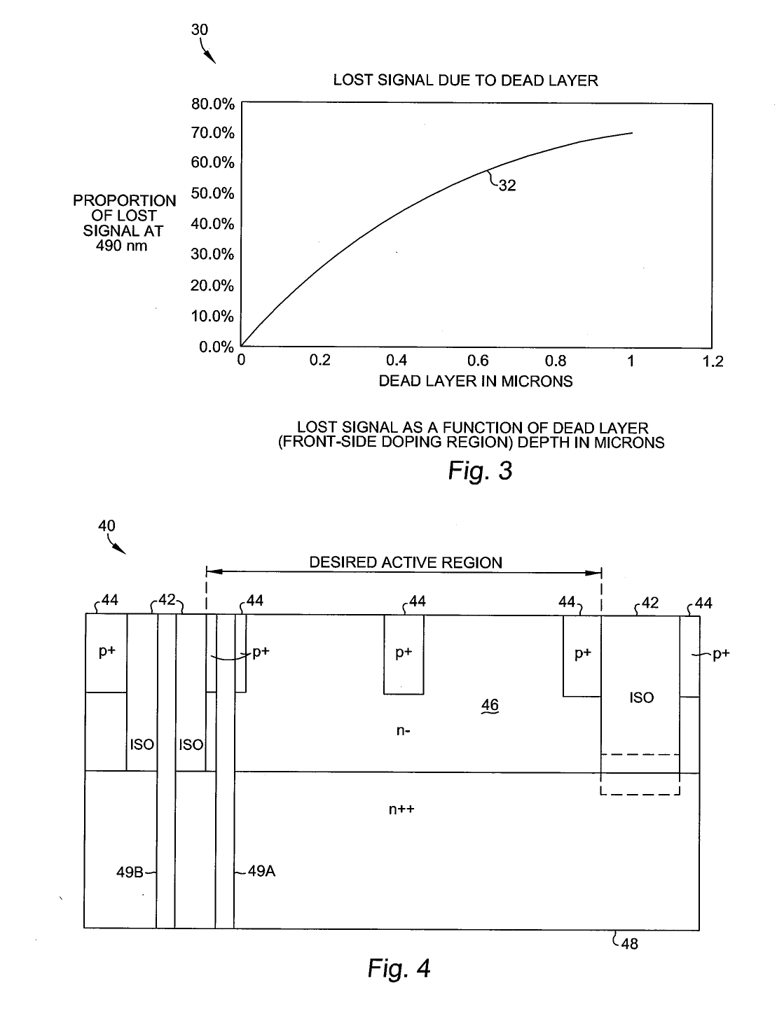

### DETAILED DESCRIPTION OF INVENTION

The photodiode 40 of the present invention circumvents the problem of dead-layer absorption by locating the front-side doping region in the septum between active photodiode pixels as shown in the cross-sectional view of FIG. 4. Using an example where the front-side plug regions or patterned layer 44 is p-type (shown as p⁺ in FIG. 4), and is formed in the front-side doped layer 46, which is n-type (shown as n⁻ in FIG. 4). The back-side doped region 48 of the photodiode 40 is also n-type (shown as n⁺⁺ in FIG. 4). In the embodiment shown in FIG. 4, the front-side plug region 44 acts as the anode of a p-i-n photodiode. In previous art, the anode would extend across the entire photodiode Desired Active Region, such that the electric field associated with the depletion region of the photodiode is essentially perpendicular to the front-side surface. In the preferred embodiment of the present invention, the front-side plug region 44 is located in the septum between pixels, such region including an isolation region 42 constructed such that light impinging upon this region does not contribute appreciable electrical signal to the pixels bordering such region.

The location of the front-side plug region 44 in the septum between adjacent pixels causes the electric field associated with the depletion region of the photodiode to be essentially parallel to the front-side surface. At some depth below the front-side surface of the photodiode, the electric field lines will curve until they become essentially perpendicular to the front-side surface and back-side surface. Thus, using the example where the front-side plug region 44 is the anode, the electrons of the electron-hole pairs generated by the absorption of light in the photodiode 40 will move along curved electric field lines and be collected approximately laterally by the anode comprised of the front-side plug region 44, while the holes of the electron-hole pairs generated by the absorption of light in the photodiode 40 will move along curved electric field lines and be collected approximately vertically by the cathode comprised of the back-side doping region 48.

Electrical connection of the front-side plug regions 44 may be made by a conductive through via 49A or 49B (isolated with oxide isolation and described in further detail below), as described in previous art, but an electrical connection may also be made by a bond pad and metal wire formed on the front-side surface. Via 49A is shown traversing p⁺ plug region 44, and an alternative via 49B is shown traversing the isolation region 42. Either via can be used in conjunction with the present invention.

In previous art, the pixel isolation region 42 was comprised of a deep silicon trench. In the preferred embodiment of the present invention, this isolation method is certainly possible; however, the pixel isolation region 42 can be alternatively comprised of a doping region of opposite type to the front-side plug region 44. In the example where the front-side plug region 44 is p-type, the pixel isolation region 42 may be an n-type doping region. The formation of the front-side plug region 44, the back-side doped region 48, and the pixel isolation region 42 may be made using well-known methods of doping in semiconductor technology such as but not limited to ion-implantation, epitaxial growth, wafer bonding, or solid source diffusion, any of which such methods may be followed by one or more thermal annealing steps to both diffuse and/or activate such doping. The isolation region 42 is shown on the left side of FIG. 4 as extending to the upper surface of the back-side doped region 48. However, on the right side of FIG. 4 an alternative embodiment is shown. The isolation region 42 can extend only partially through the front-side doped region 46, or may extend well into the back-side doped region 48 if desired for a particular application.

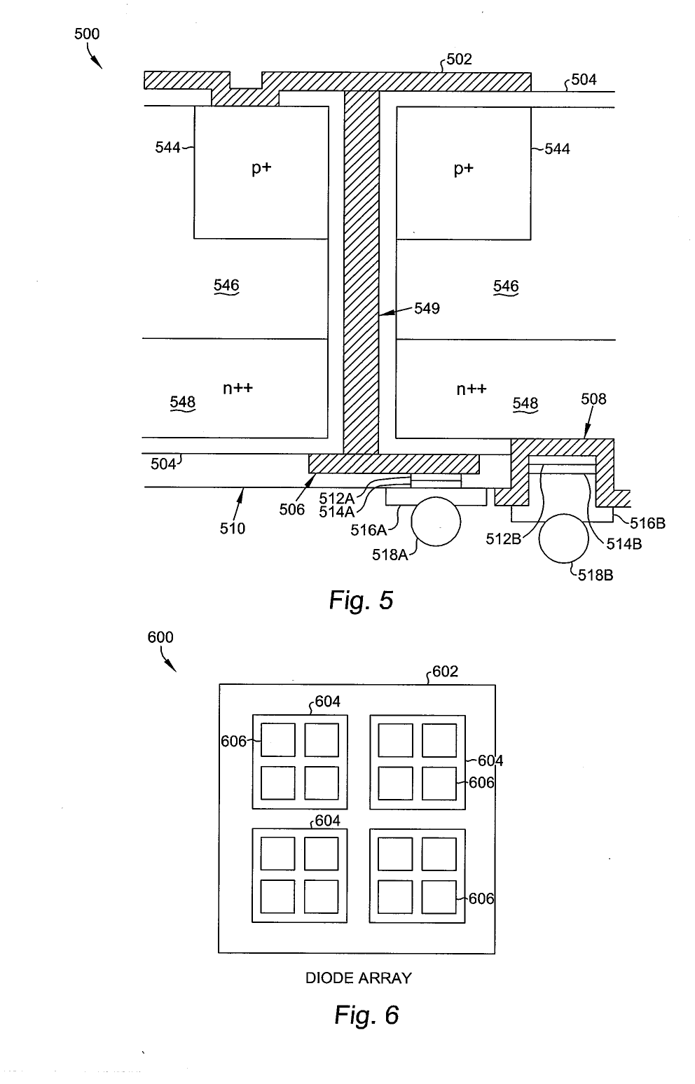

Referring now to FIG. 5, a more detailed cross-sectional view 500 of the photodiode of the present invention is shown, and in particular, revealing details related to the through-via 549. As before, photodiode 500 includes plug regions 544, front-side doped region 546, and back-side doped region 548. However, additional details are shown in FIG. 5. At the top surface of the photodiode a patterned metal layer 502 couples the via 549 to the plug region 544. Note that metal layer 502 can be extended to cover both plug regions 544. Since plug region 544 is essentially a dead-layer, it does not contribute appreciably to the generation of a photocurrent, and therefore may be hidden from the incident photons, i.e. entirely excluded from the desired active pixel region 546 that is not occluded by metal region 502. The metal via 549 thus makes contact with a front-side metal region 502, as well as a back-side metal region 506. The via 549 is completely electrically isolated from the doped regions due to oxide layer 504. The plug region is thus electrically contacted through top-side metal layer 502, via 549, and through the back-side metallization comprising metal layers 506, 512A, 514A, 516A, oxide layer 510, and metal ball 518A. In a preferred embodiment of the invention, metal layers 502 and 506 are conventional aluminum or other known metals, metal layer 512A is nickel, metal layer 514A is copper, and metal layer 516A is gold. The metal ball 518A is conventionally formed of solder, gold or other known conductive materials. The back-side electrical connection (cathode) to the photodiode is made through the metallization stack made up of metal layers 508, 512B, 514B, 516B, and metal ball 518B, which is made of similar materials to the metallization of the plug region (anode).

Referring now to FIG. 6, the front side of the photodiode 600 is shown stripped of any oxide or dielectric layers, and of any front-side metallization. Contacts are also not shown in FIG. 6. Thus, a simple plan view remains showing only the isolation region 602, the p⁺ anode region 604, and the active n⁻ regions 606. Four pixels are shown in FIG. 6, each having a crossed anode pattern.

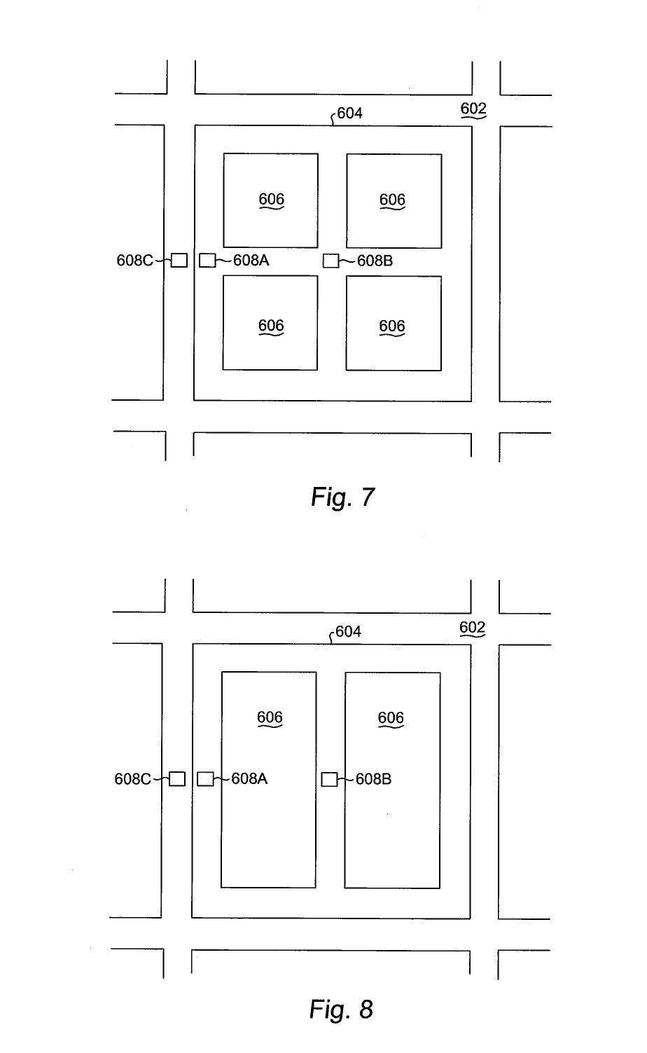

Referring now to FIG. 7 a detailed plan view of a single pixel is shown. As before, the isolation region 602, the anode region 604, and the active regions 606 are shown, wherein the anode comprises a cross pattern. However, in FIG. 7, the top-side via contacts for accessing the anode (plug regions) are shown. Contacts 608A and 608B are shown in the plug region 604, and alternative contact 608C is shown in the isolation region 602.

Referring now to FIG. 8, a detailed plan view of a single pixel for an alternative embodiment of the present invention is shown. As before, the isolation region 602, the anode region 604, and the active regions 606 are shown, wherein the anode comprises a bar pattern, coupled to a peripheral anode region. In FIG. 8, the top-side via contacts for accessing the anode (plug regions) are shown. Contacts 608A and 608B are shown in the in the plug region 604, and alternative contact 608C is shown in the isolation region 602.

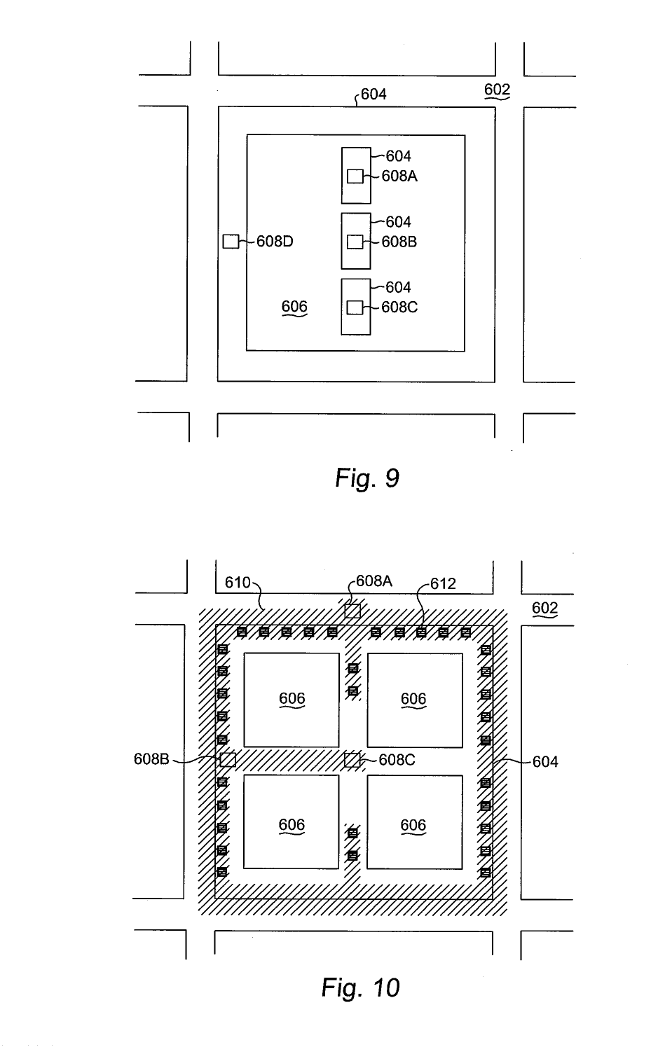

Referring now to FIG. 9 a detailed plan view of a single pixel is shown for another alternative of the present invention. As before, the isolation region 602, the anode region 604, and the active regions 606 are shown, wherein the anode comprises a segmented bar pattern that is not coupled to the peripheral anode region. In FIG. 9, the top-side via contacts for accessing the anode (plug regions) are shown. Contacts 608A, 608B, 608C are shown in each of the segmented plug regions 604, and alternative contact 608D is shown in the isolation region 604.

In addition to the embodiments of the present invention shown and described above, numerous other configurations of anode regions are possible that do not extend throughout the entire desired active pixel region.

Referring now to FIG. 10, a detailed plan view of the top-side of a pixel is shown, including the top-side metal. As before, the isolation region 602, the anode region 604, and the active regions are shown, wherein the anode comprises a cross pattern. Via contacts 608A in the isolation region, and contacts 608B and 608C in the anode region, are also shown. One or more of contacts 608A, 608B, and 608C can be used. In addition, top-side contacts 612 for the anode region are shown, which are electrically coupled to the via contacts through the top-side metal layer 610.

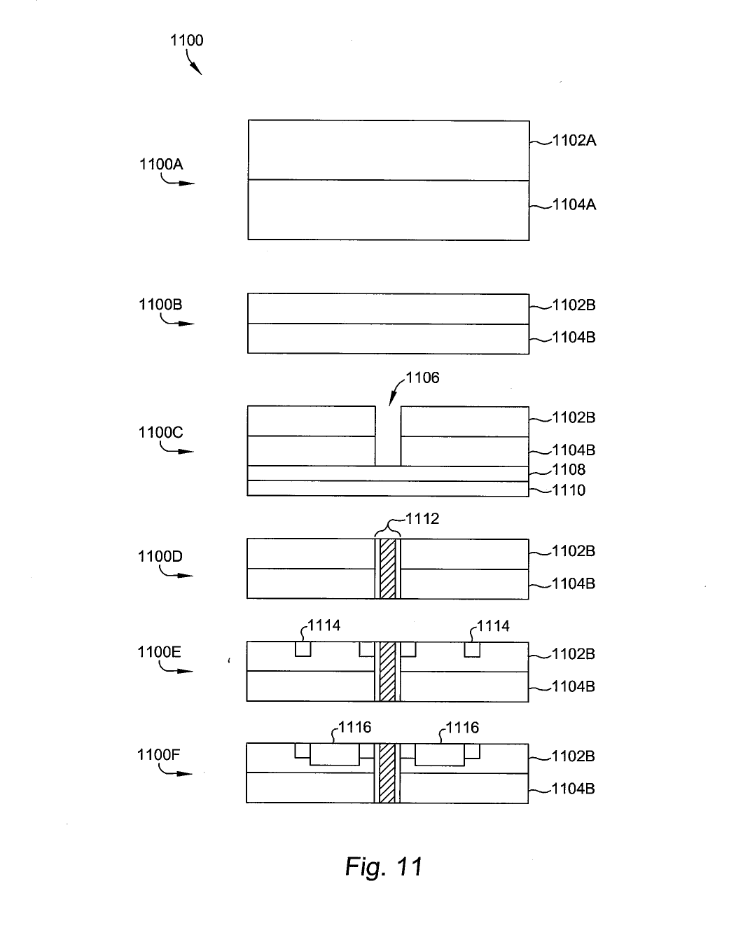

Referring now to FIG. 11, a series of cross sectional diagrams are shown that illustrate the process of forming a photodiode 1100 according to the present invention. The process flow in FIG. 11 is highly simplified, and those of skill in the art will realize that many conventional processing steps have been omitted. Also, some of the conventional processing details are also omitted. In step 1100A, a handle wafer 1104A and a top wafer 1102A are bonded together. In step 1100B, the two wafers are thinned using grinding or other known techniques, to form thinned wafers 1102B and 1104B. In step 1100C, nitride and oxide layers 1108 and 1110 are formed, that form an etch stop for forming the via trench 1106 as shown. In step 1100D, a liner oxide is formed in via 1112, and via 1112 is filled with a conducting material. In step 1100E, the p⁺ anode regions 1114 are shown. In the embodiment shown in FIG. 11, note that the via 1112 traverses the anode region. As previously described, it can also traverse the isolation region. In step 1100F, the isolation regions 1116 are formed.

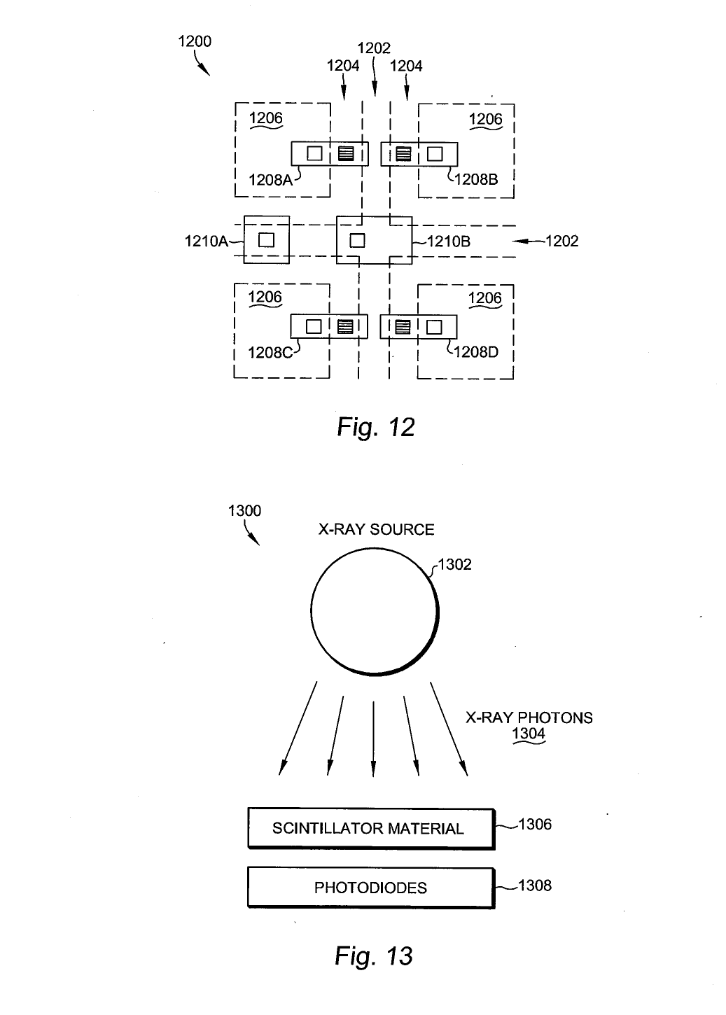

Referring now to FIG. 12, the backside 1200 of the photodiode of the present invention is shown. The backside of the isolation region 1202, the backside of the anode region 1204, and the back side of the active regions 1206 are shown in dashed lines, because these regions are obscured by thinned wafers 1102B and 1104B as shown in FIG. 11. The metallized regions 1208A, 1208B, 1208C, and 1208D connect the vias 1112 to their respective anode contact pads. Note that the anode pads may be routed to locations arbitrarily distant from the via such that the anode contact pad is not immediately adjacent to its active pixel region 1206. The metallized regions 1210A and 1210B connect the backside cathode region 1200 to one or more backside cathode contact pads. Just as with the anode contact pads, the cathode contact pads may be located arbitrarily distant from the region where such metallization 1210A and 1210B make contact to the backside cathode region 1200.

FIG. 13 shows an X-ray imaging system 1300 incorporating an X-ray detector comprised of an X-ray source 1302 for emitting X-ray photos 1304, a scintillator material 1306 coupled to a photodiode structure 1308 including a plurality of photodiodes according to the present invention. The X-ray imaging system 1300 can comprise a computed tomography system, a digital radiography system, an X-ray baggage security scanner, or other known X-ray systems.

It will be apparent to those skilled in the art that various modifications and variations can be made to the invention without departing from the spirit or scope of the invention. For example, numerous geometric features have been shown and described in conjunction with the layout embodiments of the photodiode of the present invention. As will be appreciated by those skilled in the art, all of these geometric features can be changed as required, as well as the placement of the contacts, and the shape of the metal regions. Thus, it is intended that the present invention covers the modifications and variations of this invention provided they come within the scope of the appended claims and their equivalents.

What is claimed is:

1. A photodiode structure having an illuminated front-side surface and a back-side surface, comprising:
a front-side doped layer having a first conductivity type;
a back-side doped layer having the first conductivity type;
a front-side active cell region made sensitive to light by the action of at least one plug region formed in the front-side doped layer having a second conductivity type; and
a front-side inactive cell region substantially insensitive to light,
wherein the first and second conductivity types are opposite conductivity types, and wherein the at least one plug region does not extend throughout the entire front-side active cell region.

2. The photodiode structure of claim 1 including a via traversing the at least one plug region.

3. The photodiode structure of claim 1 including a via traversing the inactive cell region.

4. The photodiode structure of claim 1 wherein the first conductivity type comprises an n-type conductivity type, and the second conductivity type comprises a p-type conductivity type.

5. The photodiode structure of claim 1 wherein the first conductivity type comprises a p-type conductivity type, and the second conductivity type comprises an n-type conductivity type.

6. The photodiode structure of claim 1 wherein the inactive cell region comprises a silicon trench or a heavily doped region of the first conductivity type.

7. The photodiode structure of claim 1 wherein the back-side doped layer comprises a cathode, and the at least one plug region comprises an anode.

8. The photodiode structure of claim 1 wherein the back-side doped layer comprises an anode, and the at least one plug region comprises a cathode.

9. The photodiode structure of claim 1 wherein the front-side inactive cell region comprises a pixel isolation region.

10. The photodiode structure of claim 9 wherein the pixel isolation regions are comprised of deep trenches, the trenches filled with non-conductive materials including oxide or a combination of oxide and intrinsic, polycrystalline semiconductor.

11. The photodiode structure of claim 1 comprising a silicon or GaAs photodiode structure.

12. A photodiode structure having an illuminated front-side surface and a back-side surface, comprising:
a plurality of photodiode cells, each photodiode cell comprising:
a front-side doped layer having a first conductivity type;
a back-side doped layer having the first conductivity type;
a front-side active cell region made sensitive to light by the action of at least one plug formed in the front-side doped layer having a second conductivity type; and
a front-side inactive cell region substantially insensitive to light,
wherein the first and second conductivity types are opposite conductivity types, and wherein the at least one plug region does not extend throughout the entire front-side active cell region.

13. The photodiode structure of claim 12 including a via traversing the at least one plug region.

14. The photodiode structure of claim 12 including a via traversing the inactive cell region.

15. The photodiode structure of claim 12 wherein the first conductivity type comprises an n-type conductivity type, and the second conductivity type comprises a p-type conductivity type.

16. The photodiode structure of claim 12 wherein the first conductivity comprises a p-type conductivity type, and the second conductivity type comprises an n-type conductivity type.

17. The photodiode structure of claim 12 wherein the inactive cell region comprises a silicon trench or a heavily doped region of the first conductivity type.

18. The photodiode structure of claim 12 wherein the back-side doped layer comprises a cathode, and the at least one plug region comprises an anode.

19. The photodiode structure of claim 12 wherein the back-side doped layer comprises an anode, and the at least one plug region comprises a cathode.

20. The photodiode structure of claim 12 wherein the front-side inactive cell region comprises a pixel isolation region.

21. The photodiode structure of claim 20 wherein the pixel isolation region is comprised of deep trenches, the trenches filled with non-conductive materials including oxide or a combination of oxide and intrinsic, polycrystalline semiconductor.

22. The photodiode structure of claim 12 comprising a silicon or GaAs photodiode structure.

23. A photodiode structure having an illuminated front-side surface and a back-side surface, comprising:
a front-side doped layer having a first conductivity type;
a back-side doped layer having the first conductivity type;
a front-side active cell region made sensitive to light by the action of at least one plug region formed in the front-side doped layer having a second conductivity type; and
a front-side inactive cell region substantially insensitive to light,
wherein the first and second conductivity types are opposite conductivity types, and wherein the at least one plug region is entirely outside of the front-side active cell region.

24. The photodiode of claim 23 including a via traversing the at least one plug region.

25. The photodiode of claim 23 including a via traversing the inactive cell region.

26. The photodiode structure of claim 23 wherein the first conductivity type comprises an n-type conductivity type, and the second conductivity type comprises a p-type conductivity type.

27. The photodiode structure of claim 23 wherein the first conductivity type comprises a p-type conductivity type, and the second conductivity type comprises an n-type conductivity type.

28. The photodiode structure of claim 23 wherein the inactive cell region comprises a silicon trench or a heavily doped region of the first conductivity type.

29. The photodiode structure of claim 23 wherein the back-side doped layer comprises a cathode, and the at least one plug region comprises an anode.

30. The photodiode structure of claim 23 wherein the back-side doped layer comprises an anode, and the at least one plug region comprises a cathode.

31. The photodiode structure of claim 23 wherein the front-side inactive cell region comprises a pixel isolation region.

32. The photodiode structure of claim 31 wherein the pixel isolation regions are comprised of deep trenches, the trenches filled with non-conductive materials including oxide or a combination of oxide and intrinsic, polycrystalline semiconductor.

33. The photodiode structure of claim 23 comprising a silicon or GaAs photodiode structure.

34. A method of fabricating a photodiode structure having an illuminated front-side surface and a back-side surface, comprising:
forming a front-side doped layer having a first conductivity type;
forming a back-side doped layer having the first conductivity type;
forming a front-side active cell region made sensitive to light by the action of at least one plug region formed in the front-side doped layer having a second conductivity type; and
forming a front-side inactive cell region insensitive to light,
wherein the first and second conductivity types are opposite conductivity types, and wherein the at least one plug region does not extend throughout the entire front-side active cell region, and/or may be obscured from front-side illumination.

35. An X-ray imaging system incorporating an X-ray detector comprised of a scintillator material coupled to a photodiode structure having an illuminated front-side surface and a back-side surface, the photodiode structure comprising:
a front-side doped layer having a first conductivity type;
a back-side doped layer having the first conductivity type;
a front-side active cell region made sensitive to light by the action of at least one plug region formed in the front-side doped layer having a second conductivity type; and
a front-side inactive cell region substantially insensitive to light,
wherein the first and second conductivity types are opposite conductivity types, and wherein the at least one plug region does not extend throughout the entire front-side active cell region.

36. The X-ray imaging system of claim 35 wherein the X-ray imaging system comprises a computed tomography system.

37. The X-ray imaging system of claim 35 wherein the X-ray imaging system comprises a digital radiography system.

38. The X-ray imaging system of claim 35 wherein the X-ray imaging system comprises an X-ray baggage security scanner.
